(19) United States
(12) Patent Application Publication
(10) Pub. No.: US 2026/0123476 A1
(43) Pub. Date: Apr. 30, 2026

(54) BOTTOM-UP ELECTROPLATED VIAS FOR PACKAGE SUBSTRATES AND RELATED METHODS

(71) Applicant: Intel Corporation, Santa Clara, CA (US)

(72) Inventors: Thomas Stanley Heaton, Gilbert, AZ (US); Lei Jin, Chandler, AZ (US); Houssam Wafic Jomaa, San Diego, CA (US); Jieying Kong, Chandler, AZ (US); Wendy Jessica Lin, Chandler, AZ (US); Son Van Nguyen, Gilbert, AZ (US); Travis Charles Palmer, San Diego, CA (US); Dilan Seneviratne, Phoenix, AZ (US); Richard Surmaitis, Scottsdale, AZ (US); David Vickery, Gilbert, AZ (US); Ao Wang, Chandler, AZ (US)

(73) Assignee: Intel Corporation, Santa Clara, CA (US)

(21) Appl. No.: 18/955,570

(22) Filed: Nov. 21, 2024

(51) Int. Cl. H01L 23/498; H01L 23/15

(52) U.S. Cl. CPC H10W 70/635; H10W 70/692

(57) ABSTRACT

Plated vias for package substrates and related methods are disclosed. A substrate disclosed herein including a core including an opening having an internal wall and an interconnect extending through the core, the interconnect including an outer surface spaced from the internal wall by at least one gap.

### BACKGROUND

Integrated circuit (IC) chips and/or semiconductor dies are routinely connected to larger circuit boards such as motherboards and other types of printed circuit boards (PCBs) via a package substrate. As IC chips and/or dies reduce in size and interconnect densities increase, alternatives to traditional substrate layers are being developed to provide stable transmission of high-frequency data signals between different circuitry and/or increased power delivery.

### BRIEF DESCRIPTION OF THE DRAWINGS

FIG. 1 illustrates an example integrated circuit (IC) package constructed in accordance with teachings disclosed herein.

FIG. 2A illustrates a cross-sectional side view of an example glass core of the IC package of FIG. 1 and a plurality of vias extending therethrough.

FIG. 2B is a detail view of an interface between a via and the glass core of FIG. 2B.

FIGS. 3-9 illustrate different intermediate stages in an example first fabrication process to manufacture the glass core and vias of FIGS. 1-2B.

FIGS. 10-15 illustrate different intermediate stages in an example second fabrication process to manufacture an alternative glass core that can be used in conjunction with the IC package of FIG. 1.

FIG. 16 is a flowchart representative of example methods that may be performed to fabricate the glass cores of FIGS. 2-15.

FIG. 17 is a top view of a wafer including dies that may be included in an IC package constructed in accordance with teachings disclosed herein.

FIG. 18 is a cross-sectional side view of an IC device that may be included in an IC package constructed in accordance with teachings disclosed herein.

FIG. 19 is a cross-sectional side view of an IC device assembly that may include an IC package constructed in accordance with teachings disclosed herein.

FIG. 20 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

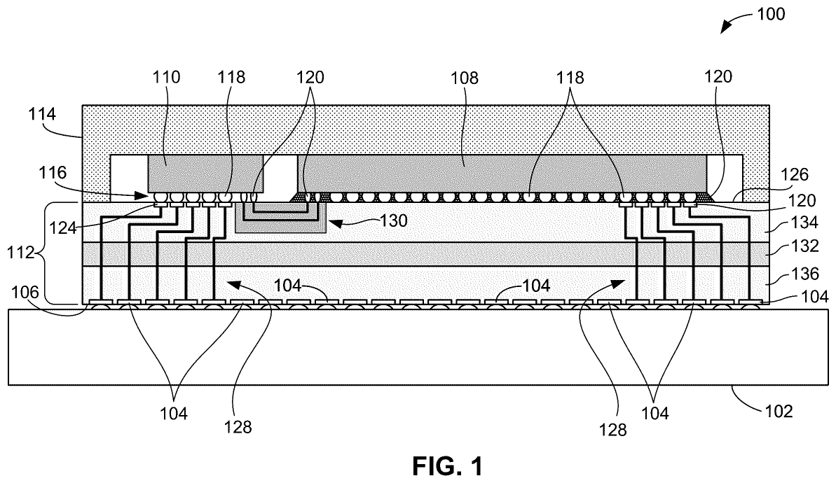

FIG. 1 illustrates an example integrated circuit package 100 constructed in accordance with teachings disclosed herein. In the illustrated example, the IC package 100 includes an underlying substrate 102 via an array of contacts 104 on a package mounting surface 106 (e.g., a bottom surface, an external surface) of the package. In some examples, the substrate 102 can be implemented by a package substrate or a printed circuit board (PCB). In the illustrated example, the contacts 104 are represented as pads or lands. However, in some examples, the IC package 100 may include balls, pins, and/or any other type of contact, in addition to or instead of the pads or lands shown to enable the electrical coupling of the IC package 100 to the substrate 102. In this example, the IC package 100 includes two dies 108, 110 (e.g., silicon dies, semiconductor dies, etc.), sometimes also referred to as chips or chiplets, that are mounted to a package substrate 112 and enclosed by a package lid 114 (e.g., a mold compound, an integrated heat spreader (IHS)). Thus, the package substrate 112 is an example means for supporting a semiconductor die. While the example IC package 100 of FIG. 1 includes two dies 108, 110, in other examples, the IC package 100 may have only one die or more than two dies. In some examples, one of the dies 108, 110 (or a separate die) is embedded in the package substrate 112. The dies 108, 110 can provide any suitable type of functionality (e.g., data processing, memory storage, etc.). In some examples, one or both of the dies 108, 110 are implemented by a die package including multiple dies arranged in a stacked formation. For example, the second die 110 can include a stack of Dynamic Random Access Memory (DRAM) die arranged on top of a memory controller die to form a memory die stack.

As shown in the illustrated example, each of the dies 108, 110 is electrically and mechanically coupled to the package substrate 112 via corresponding arrays of interconnects 116. In FIG. 1, the interconnects are shown as bumps. The interconnects 116 can include solder joints, micro bumps, combinations of metallic (e.g., copper) pillars and solder, etc. In other examples, the interconnects 116 may include directly bonded or “hybrid bonded” metallic interconnects. In other examples, the interconnects 116 may be any other type of electrical connection in addition to or instead of the bumps shown (e.g., balls, pins, pads, pillars, wire bonding, etc.). The electrical connections between the dies 108, 110 and the package substrate 112 (e.g., the interconnects 116) are sometimes referred to as first level interconnects. By contrast, the electrical connections between the IC package 100 and the substrate 102 (e.g., the contacts 104) are sometimes referred to as second level interconnects. In some examples, one or both of the dies 108, 110 may be stacked on top of one or more other dies and/or an interposer. In such examples, the dies 108, 110 are coupled to the underlying die and/or interposer through a first set of first level interconnects and the underlying die and/or interposer may be connected to the package substrate 112 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the first level interconnects 116 include two different types of bumps corresponding to core bumps 118 and bridge bumps 120. As used herein, the core bumps 118 are bumps on the dies 108, 110 through which electrical signals pass between the dies 108, 110 and components external to the IC package 100. More particularly, as shown in the illustrated example, when the dies 108, 110 are mounted to the package substrate 112, the core bumps 118 are physically connected and electrically coupled to contact pads 124 on a die mounting surface 126 (e.g., an upper surface, a top surface, etc.) of the package substrate 112. The contact pads 124 on the die mounting surface 126 of the package substrate 112 are electrically coupled to the contacts 104 on the package mounting surface 106 (e.g., the bottom, external surface) of the package substrate 112 (e.g., a surface opposite the die mounting surface 126) via internal interconnects 128 within the package substrate 112. As a result, there is an electrical signal path between the core bumps 118 of the dies 108, 110 and the contacts 104 mounted to the substrate 102 that pass through the contact pads 124 and the internal interconnects 128 provided therebetween. As shown, the package mounting surface 106 and the die mounting surface 126 define opposing outer surfaces of the package substrate 112. While both surfaces are outer surfaces of the package substrate, the die mounting surface 126 is sometimes referred to herein as an internal or inner surface relative to the IC package 100. By contrast, in this example, the package mounting surface 106 is an outer or exterior surface of the IC package 100.

As used herein, the bridge bumps 120 are bumps on the dies 108, 110 through which electrical signals pass between different ones of the dies 108, 110 within the IC package 100. Thus, as shown in the illustrated example, the bridge bumps 120 of the first die 108 are electrically coupled to the bridge bumps 120 of the second die 110 via an interconnect bridge 130 (e.g., a silicon-based interconnect bridge, an interconnect die, an embedded interconnect bridge (EMIB)) embedded in the package substrate 112. As represented in FIG. 1, core bumps 118 are typically larger than bridge bumps 120. In some examples, interconnect bridge 130 and the associated bridge bumps 120 are omitted.

In some examples, an underfill material 122 is between the dies 108, 110 and the package substrate 112 around and/or between the first level interconnects 116 (e.g., around and/or between the core bumps 118 and/or the bridge bumps 120). In the illustrated example, only the first die 108 is associated with the underfill material 122. However, in other examples, both dies 108, 110 are associated with the underfill material 122. In other examples, the underfill material 122 is omitted. In some examples, the mold compound used for the package lid 114 is used as an underfill material that surrounds the first level interconnects 116.

In some examples, the IC package 100 includes additional passive components, such as surface-mount resistors, capacitors, and/or inductors disposed on the package mounting surface 106 of the package substrate 112 and/or the die mounting surface 126 of the package substrate 112.

In FIG. 1, the package substrate 112 of the example IC package 100 includes a glass core 132 (e.g., a glass substrate, a glass layer, etc.) between two separate build-up regions 134, 136 (also referred to herein as build-up layers, etc.). In some examples, the glass core 132 includes at least one of: aluminosilicate, borosilicate, alumino-borosilicate, silica, and/or fused silica. In some examples, the glass core 132 includes one or more additives including: aluminum oxide (Al₂O₃), boron trioxide (B₂O₃), magnesia oxide (MgO), calcium oxide (CaO), stoichiometric silicon oxide (SrO), barium oxide (BaO), stannic oxide (SnO₂), nickel alloy (Na₂O), potassium oxide (K₂O), phosphorus trioxide (P₂O₃), zirconium dioxide (ZrO₂), lithium oxide (Li₂O), titanium (Ti), and/or zinc (Zn). In some examples, the glass core 132 includes silicon and oxygen. In some examples, the glass core 132 includes silicon, oxygen and/or one or more of aluminum, boron, magnesium, calcium, barium, tin, sodium, potassium, strontium, phosphorus, zirconium, lithium, titanium, and/or zinc. In some examples, the glass core 132 includes at least 23 percent silicon by weight and at least 26 percent oxygen by weight. In some examples, the glass core is a layer of glass including silicon, oxygen, and aluminum. In some examples, the glass core 132 includes at least 23 percent silicon by weight, at least 26 percent oxygen by weight, and at least 5 percent aluminum by weight.

In some examples, the glass core 132 is an amorphous solid glass layer. In some examples, the glass core 132 is a layer of glass that does not include an organic adhesive or an organic material. In some examples, the glass core 132 is a solid layer of glass having a rectangular shape in plan view. In some examples, the glass core 132, as a glass substrate, includes at least one glass layer and does not include epoxy and does not include glass fibers (e.g., does not include an epoxy-based prepreg layer with glass cloth). In some examples, the glass core 132 corresponds to a single piece of glass that extends the full height/thickness of the core. In other examples, the glass core 132 can be silicon, a dielectric material, and/or any other material(s).

In some examples, the glass core 132 has a rectangular shape that is substantially coextensive (e.g., within 10%), in plan view, with the layers above and/or below the core. In some examples, the glass core 132 has a thickness in a range of about 50 micrometers (μm) to about 1.4 millimeters (mm). In some examples, the glass core 132 can be a multi-layer glass substrate (e.g., a coreless substrate), where a glass layer has a thickness in a range of about 25 μm to about 50 μm. In some examples, the glass core 132 can have dimensions of about 10 mm on a side to about 250 mm on a side (e.g., 10 mm by 10 mm to 250 mm by 250 mm). In some examples, the glass core 132 corresponds to a rectangular prism volume with sections (e.g., vias) removed and filled with other materials (e.g., metal). Among other things, glass cores are advantageous over epoxy-based cores because glass is stiffer and, therefore, provides greater mechanical support or strength for the package substrate. Thus, the glass core 132 is an example means for strengthening the package substrate.

The build-up regions 134, 136 are represented in FIG. 1 as masses/blocks with the internal interconnects 128 extending in straight lines through the build-up regions 134, 136 (and the glass core 132). However, FIG. 1 has been simplified for the sake of clarity and purposes of explanation. In practice, the interconnects are not necessarily straight. More particularly, in some examples, the build-up regions 134, 136 are defined by alternating layers of dielectric material and layers of conductive material (e.g., a metal such as copper). The conductive (metal) layers serve as the basis for the internal interconnects 128 represented, in a simplified form, by straight lines as shown in FIG. 1. In some examples, the metal layers are patterned to define electrical routing or conductive traces that are electrically coupled between different metal layers by conductive (e.g., metal) vias extending through intervening dielectric layers.

Using glass as a starting core material (e.g., the glass core 132 of FIG. 1) has a mechanical benefit (e.g., reduced warpage, smaller thickness variation), an electrical benefit, and a design flexibility benefit (e.g., tighter through-hole pitch, finer core routing) over using traditional organic core materials (e.g., epoxy-based prepreg). For example, the glass core 132 can support multi-chip packaging (e.g., embedded multi-die interconnect bridge (EMIB), 2.5D/3D heterogeneous integration, hyper chip stacking (silicon (Si) interposers), etc.), reduced first level interconnect (FLI) bump pitches (e.g., less than 30 micrometer (μm)), reduced fine line spacing (FLS) (e.g., 2/2 μm), higher density interconnects, higher input/output (I/O) density patterning, increasing form factors, and decreasing package thicknesses over the traditional organic core materials. To further facilitate these advantages, the glass core 132 can include through-glass vias (TGVs) (e.g., copper-plated vias) extending through the glass core 132 to electrically couple the build-up region 134 to the build-up region 136. While examples described herein are described with reference to the glass core 132, it should be appreciated that teachings of this disclosure are not limited thereto. For example, the teachings of this disclosure are also applicable to organic cores.

A common type of failure of known glass cores is a seware failure. Seware failures result in the separation of a glass core along a crack that propagates from an edge of the glass core along its length and width between two or more of the outer surfaces (e.g., the upper and lower surfaces, the front and back surfaces, etc.) of the glass core. That is, seware failures are characterized by a glass core splitting into two separate sheets of glass along a line extending generally parallel to the main plane of the glass core. Factors that contribute to seware failures include mismatches in the thermal expansion of materials of the package substrate 112. For example, differences in the coefficients of thermal expansion (CTEs) between copper and glass induce shear stress at interfaces between the copper plating in the TGVs and the glass core 132. Such an interface can be located adjacent to an inner wall of an opening of the glass core 132 and is where the inner wall contacts the copper of a TGV. In such examples, a defect (e.g., a crack, warpage, etc.) forms in the inner wall in response to the shear stress caused by the expansion and/or contraction of the copper relative to the glass. For example, as the IC package 100 undergoes thermal treatments or other high-temperature processes, the copper in the TGV expands and pushes against the inner wall of the opening in the glass core 132. In some such examples, the inner wall cracks under the force of the expanding copper. These defects can reduce the reliability of the glass core 132 and, thus, can necessitate repair and/or replacement of the glass core 132. Previous solutions to overcome cracking in the glass core 132 include stress-absorbing liners (e.g., parylene liners, etc.) and conformally plated TGVs. However, the stress-absorbing liners are financially costly and time expensive to deposit on the TGVs. Further, conformally plated TGVs limit TGV pitch and size scaling.

Another problem associated with prior TGVs is the formation of voids within the conductive material of the TGVs. Some prior TGVs are formed by depositing wet seed layers via electroless plating on the inner walls of the openings extending through the glass core and electroplating the conductive material of the TGV from such deposited seed layers. As the conductive material of the TGV is deposited from the outer wall of the hole inward, certain portions of the TGV can form a seal in the center thereof and cause the formation of voids within the body of the TGV. The conductive material blocks the flow of the electroplating fluid and prevents the deposition of additional conductive material within the voids. Such voids can prevent and/or severely reduce the flow of electricity through the TGVs, which can result in the glass core being rendered inoperable and discarded. Additionally, this wet seeding process often involves the agitation of the core to dislodge hydrogen bubbles in the wet seed layer, which can damage the glass core. Previous solutions to mitigate void formation in TGVs include tapering the side walls of the TGVs such that the openings of the TGVs are wider than the midpoint of the TGVs. However, the tapering of TGVs severely limits the maximum aspect ratio of the TGV, which limits the density of TGVs within the glass core and the use of thick glass cores.

Another problem associated with the deposition of prior TGVs is the deposition of conductive material outside of the through holes of the core. This material extends from the top and bottom surfaces of the core. In some applications, the TGVs must be flush with the top and bottom surfaces of the glass core. As such, this material must be removed via subsequent manufacturing steps, which adds manufacturing time, cost, and complexity to the fabrication of package substrates. Additionally, these manufacturing processes can damage a glass core and/or cause unfavorable surface finishes on the top and bottom surfaces of the glass core.

Examples disclosed herein mitigate (e.g., reduce, prevent, etc.) some or all of the above deficiencies of prior TGV deposition processes and include glass cores with bottom-up plated TGVs. An example TGV deposition process disclosed herein includes the plating of TGVs from a multi-layer conductive film deposited on the bottom of the glass core. Example multi-layer conductive films disclosed herein include a non-conductive backing layer, a second conductive metallic layer, and a conductive adhesive layer. In some examples disclosed herein, the multi-layer conductive film is coupled to the glass core, and the flow of electricity is induced therethrough, which enables the TGVs to be electroplated from the multi-layer conductive film through the glass core. Some examples disclosed herein include a copper adhesion promoter, such as imidazole, on the inner surfaces of the glass core. Example glass cores disclosed herein include through holes with at least gap, void, and/or pocket between the inner wall of the through holes and the outer wall of the TGVs positioned therein, which enables the TGVs to thermally expand without contacting the body of the glass core. Example TGV deposition processes disclosed herein include plating the TGV from the bottom of the glass core up therethrough, which reduces (e.g., prevents, etc.) the formation of voids within the TGV and the deposition of extra material on the top and bottom surfaces of the glass core.

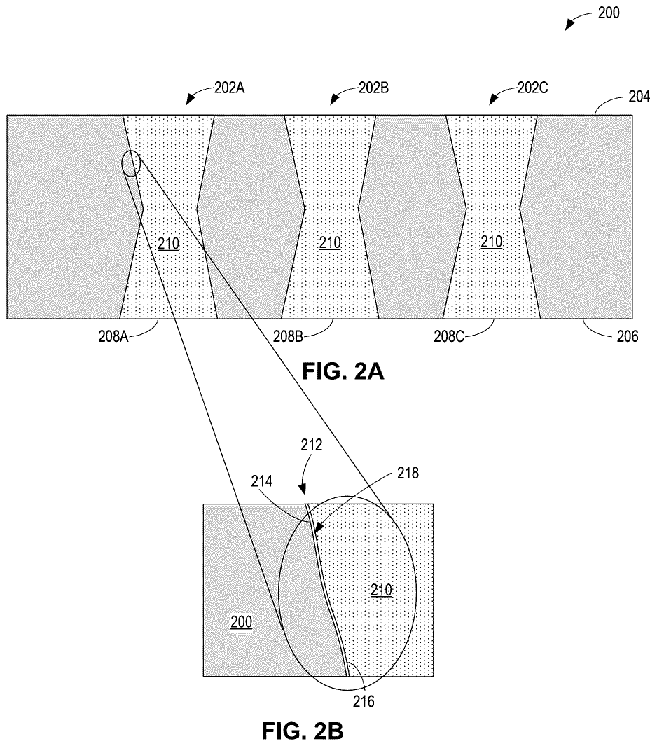

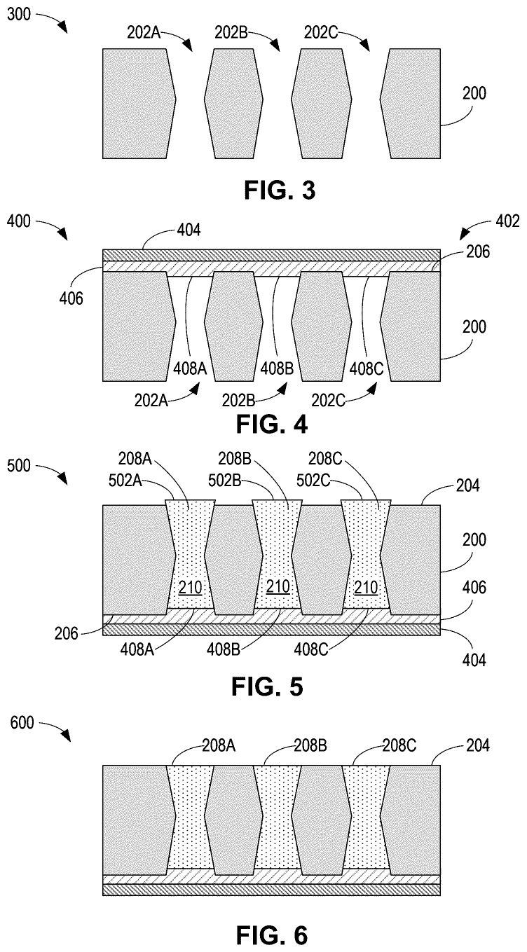

FIG. 2A is a cross-sectional view of an example glass core 200 constructed in accordance with teachings disclosed herein. The glass core 200 can implement the glass core 132 of FIG. 1. In the illustrated example of FIG. 2A, the glass core 200 includes an example first opening 202A, an example second opening 202B, and an example second opening 202C, which extend between an example first surface 204 and an example second surface 206 of the glass core 200. In the illustrated example of FIG. 2A, the first surface 204 (e.g., a top surface, etc.) is opposite the second surface 206 (e.g., a bottom surface, etc.). In the illustrated example of FIG. 2A, the glass core 200 includes an example first via 208A, an example second via 208B, and an example third via 208C positioned in the openings 202A, 202B, 202C, respectively. In the illustrated example of FIG. 2A, the vias 208A, 208B, 208C include (e.g., contain, are composed of, etc.) an example conductive material 210.

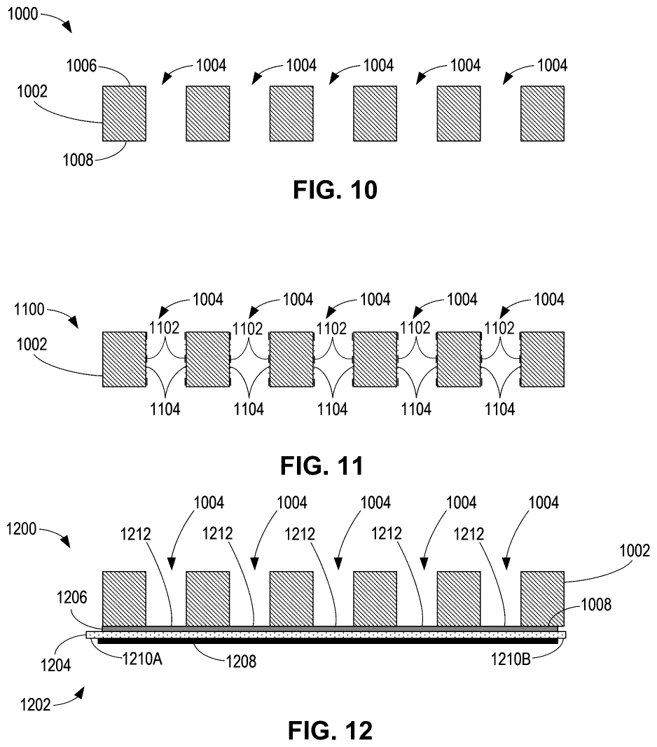

In the illustrated example of FIG. 2A, the openings 202A, 202B, 202C are through holes (e.g., cavities, etc.) that extend through the glass core 200. In the illustrated example of FIG. 2A, the openings 202A, 202B, 202C are generally hourglass shaped. That is, the openings 202A, 202B, 202C and the vias 208A, 208B, 208C positioned therein have a tapered cross-sectional profile, such that the width (e.g., diameter) of the openings 202A, 202B, 202C is narrower near a midpoint of the openings 202A, 202B, 202C between the first surface 204 and second surface 206 of the glass core 200. In other examples, one or more of the openings 202A, 202B, 202C have a different cross-sectional shape. For instance, in some examples, one or more of the openings 202A, 202B, 202C may have a generally conical or tapered shape with the width (e.g., diameter) being smallest at one of the two surfaces 204, 206 of the glass core 200 and the width (e.g., diameter) being largest at the surfaces 204, 206. In the illustrated example of FIG. 2A, the openings 202A, 202B, 202C and the vias 208A, 208B, 208C have an aspect ratio of 8:1 (e.g., a ratio of width at the surfaces 204, 206 to the thickness of the glass core, etc.). In other examples, the openings 202A, 202B, 202C can have different shapes and/or aspect ratios. Some example methods for depositing vias disclosed herein enable the openings 202A, 202B, 202C to be straight walled, such that the openings 202A, 202B, 202C have a constant width along the length of the glass core 200. A glass core with straight-walled openings and vias is described below in conjunction with FIGS. 10-15. In some such examples, the openings 202A, 202B, 202C and vias 208A, 208B, 208C have an aspect ratio greater than 8:1 (e.g., 10:1, 50:1, 100:1, etc.).

The vias 208A, 208B, 208C are conductive interconnects that enable the transmission of electrical signals and power through the glass core 200 (e.g., between a first component mounted on the first surface 204 and a second component mounted on the second surface 206, etc.). In the illustrated example of FIG. 2A, each of the vias 208A, 208B, 208C is a single monolithic component (e.g., a monolithic body of copper, etc.). In the illustrated example of FIG. 2A, the vias 208A, 208B, 208C have been deposited within the openings 202A, 202B, 202C, respectively, via electroplating from a conductive material disposed adjacent to the second surface 206 of the glass core 200 (e.g., bottom-up plating, etc.). In some examples, the plating of the vias 208A, 208B, 208C from the bottom of the glass core 200 causes the vias 208A, 208B, 208C to be spaced from the inner walls of the openings 202A, 202B, 202C via at least one gap, cavity, or pocket (e.g., an air gap, etc.). That is, because the vias 208A, 208B, 208C are plated from the bottom of the glass core 200 and not the sides of the openings 202A, 202B, 202C, some portions of the vias 208A, 208B, 208C do not abut (e.g., are not in contact with, etc.) the sides of the openings 202A, 202B, 202C. thereby creating one or more pockets. In some examples, other portions of the vias 208A, 208B, 208C abut (e.g., are in contact with, etc.) the sides of the openings 202A, 202B, 202C. In some examples, an annular air gap is formed between respective ones of the vias 208A, 208B, 208C and the corresponding sides of the openings 202A, 202B, 202C. In some examples, the annular air gap may completely surround the corresponding via. In other examples, there are contact points between the respective ones of the vias 208A, 208B, 208C and the corresponding sides of the openings 202A, 202B, 202C, thereby forming one or more cavities or pockets rather than complete separation between the respective ones of the vias 208A, 208B, 208C and the corresponding sides of the openings 202A, 202B, 202C.

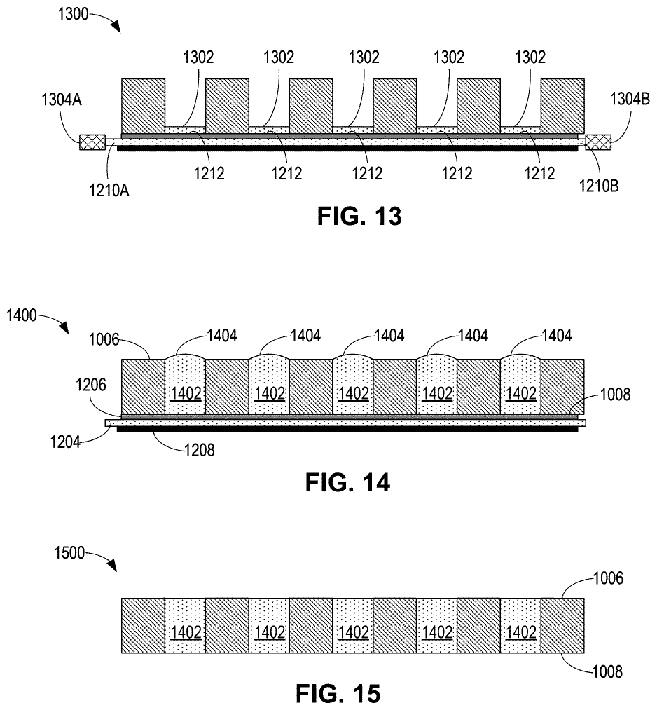

An example interface between the first via 208A and the inner walls of the first opening 202A is described below in conjunction with FIG. 2B. Example operations for depositing the vias 208A, 208B, 208C are described below in conjunction with FIG. 16. The conductive material 210 of the vias 208A, 208B, 208C can include one or more conductive materials (e.g., copper, silver, gold, aluminum, etc.). While the glass core 200 of FIG. 2A includes three vias (e.g., the vias 208A, 208B, 208C, etc.), in other examples, the glass core 200 can have a different quantity of vias (e.g., one vias, two vias, five vias, ten vias, one hundred vias, etc.).

FIG. 2B is a detail view of an example interface 212 between an example side wall 214 of the first opening 202A of the glass core 200 of FIG. 2 and an example outer surface 216 of the conductive material 210 of the first via 208A of FIG. 2A. In the illustrated example of FIG. 2B, the side wall 214 is adjacent to the outer surface 216. In the illustrated example of FIG. 2B, the side wall 214 is spaced from the conductive material 210 via an example gap 218 (e.g., a pocket, a cavity, etc.). In some examples, the gap 218 is an air gap. In the illustrated example of FIG. 2B, the interface 212 does not include an intervening seed layer (e.g., an electroplating seed layer, etc.) disposed between the side wall 214 and the outer surface 216 because the conductive material 210 is plated upward from the bottom of the glass core 200 and not inward from the side wall 214. In some examples, some or all of the gap 218 can include a layer of material (e.g., an adhesion promoter, a liner, etc.) positioned therein.

In the illustrated example of FIG. 2B, the gap 218 is measured perpendicularly from the outer surface 216 of the conductive material 210 to the side wall 214. In the illustrated example of FIG. 2B, the gap 218 is approximately 45 nanometers in length perpendicularly between the side wall 214 and the outer surface 216. In other examples, the gap 218 can be any suitable length between 25 nanometers to 150 nanometers. In the illustrated example of FIG. 2B, the size of the gap 218 is generally constant along the length of the side wall 214. In other examples, the size of the gap 218 varies along the length of the side wall 214 (e.g., between a magnitude of 25 nanometers to 150 nanometers, etc.). It should be appreciated that other portions of the conductive material 210 may abut the side wall 214 and/or be spaced therefrom by one or more additional gaps. In some such examples, some or all of the other gap(s), cavit(ies) and/or pocket(s) between the outer surface 216 of the conductive material 210 to the side wall 214 have different sizes, lengths, and/or profiles than the gap 218.

During operation, increases in temperature cause the thermal expansion of the glass core 200 and the first vias 208A. Because the conductive material 210 typically has a higher coefficient of thermal expansion than the glass of the glass core 200, the conductive material 210 thermally expands at a greater rate than the glass core 200. The gap 218, the cavit(ies) and/or the pocket(s) between the outer surface 216 of the conductive material 210 to the side wall 214 enable the conductive material 210 of the first via 208A to thermally expand during the manufacturing of a package substrate including the glass core 200 and/or the operation thereof without contacting the glass core 200. Additionally or alternatively, because the outer surface 216 of the conductive material 210 is at least partially (and in some examples completely) decoupled from the side wall 214 (e.g., the conductive material 210 is at least partially separated from the side wall 214 rather than being grown from a seed layer on the side wall, etc.), the conductive material 210 and the side wall 214 can undergo relative thermal expansion without applying stress to the interface 212.

The gap 218 and the at least partial of the conductive material 210 and the side wall 214 prevent potential damage to the glass core 200 from such thermal expansion of the first via 208A and increase the thermal reliability of IC packages including the glass core 200 (e.g., the IC package 100 of FIG. 1, etc.). It should be appreciated that the second via 208B and the third via 208C can have a similar configuration within the second opening 202B and the third opening 202C, respectively. That is, the second via 208B and the third via 208C can be similarly spaced via at least one gap, pocket, cavity, and/or decoupled from the inner walls of the second opening 202B and the third opening 202C, respectively.

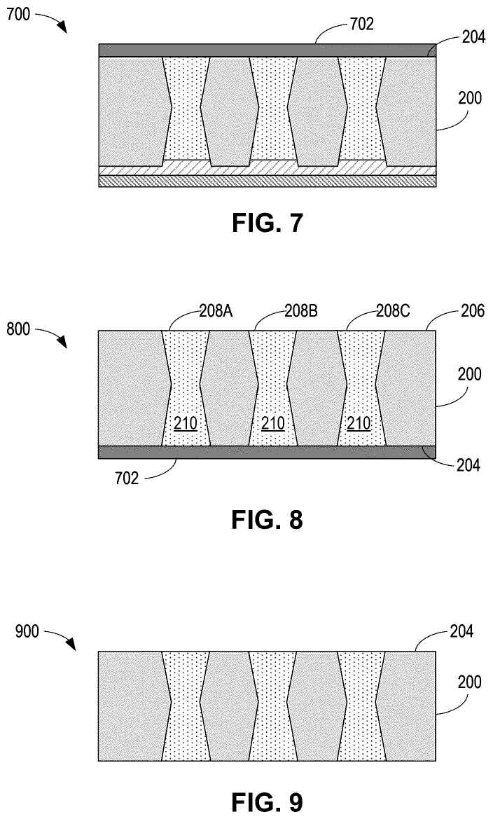

FIGS. 3-9 illustrate different intermediate stages in an example first fabrication process to manufacture the glass core 200 of FIGS. 2A and 2B. FIG. 3 is a cross-sectional schematic view of an example first intermediate stage 300 of the assembly/manufacturing of the glass core 200 of FIG. 2A. During the first intermediate stage 300, the glass core 200 is provided. In the illustrated example of FIG. 3, the glass core 200 includes the openings 202A, 202B, 202C extending therethrough. In some examples, the openings 202A, 202B, 202C can be created in the glass core 200 via laser-induced deep etching (LIDE) process. In some such examples, a laser is concentrated on defined regions of the glass core 200 corresponding to the openings 202A, 202B, 202C to modify the optical and chemical properties of such regions. In some such examples, the defined regions of the glass core exposed to the laser are chemically etched to remove the material therein and create the openings 202A, 202B, 202C. In other examples, the openings 202A, 202B, 202C can be created via one or more different operation(s), such as drilling.

FIG. 4 is a cross-sectional schematic view of an example second intermediate stage 400 of the assembly/manufacturing of the glass core 200 of FIG. 2A. In some examples, the second intermediate stage 400 can occur after the first intermediate stage 300 of FIG. 3. During the second intermediate stage 400, an example multi-layer conductive film 402 is coupled to the second surface 206 of the glass core 200. In the illustrated example of FIG. 4, the multi-layer conductive film 402 includes an example first layer 404 and an example second layer 406. In some examples, the multi-layer conductive film 402 can be coupled to the second surface 206 of the glass core 200 via a foil deposition technique. In other examples, the multi-layer conductive film 402 can be coupled to the second surface 206 via one or more other operations, such as lamination. As used herein, the multi-layer conductive film 402 is also referred to as a multi-layer conductive laminate. In some examples, the multi-layer conductive film 402 also includes a non-conductive third layer on the second layer 406 and distal to the glass core 200.

The first layer 404 is an electrically conductive layer that is distal to the second surface 206 (e.g., the second layer 406 is between the first layer 404 and the second surface 206, etc.). In some examples, the first layer 404 is an electrode layer that transmits an electric current to the second layer 406 during the electroplating of the vias 208A, 208B, 208C of FIG. 2A. In other examples, the first layer 404 can be implemented by a metal foil, such as copper foil and/or a silver foil. In the illustrated example of FIG. 4, the first layer 404 is the same size as the second layer 406. In other examples, the first layer 404 is larger (e.g., has a larger area, etc.) than the second layer 406 to facilitate the coupling of the first layer 404 to an electricity source (e.g., an electrode, etc.).

The second layer 406 is an electrically conductive adhesive layer (e.g., a doped conductive adhesive, etc.) that is coupled to the second surface 206 of the glass core 200 (e.g., the second layer 406 adheres to the second surface 206, etc.). In some examples, the second layer 406 can be implemented by a doped resin (e.g., a resin-based adhesive that is doped with a conductive material, etc.). In some such examples, the dopant of the second layer 406 can be metal particles (e.g., copper particles, silver particles, etc.). In other examples, the second layer 406 can be implemented by any other suitable conductive adhesive. In some examples, the surface of the second layer 406 adjacent to the second surface 206 of the glass core 200 can be modulated to have a higher concentration of the dopant to increase the active sites to facilitate the electroplating of the vias 208A, 208B, 208C therefrom. In other examples, the dopant is evenly distributed in the second layer 406. In the illustrated example of FIG. 4, the deposition of the multi-layer conductive film 402 on the glass core 200 creates an example first exposed portion 408A, an example second exposed portion 408B, and an example third exposed portion 408C on the second layer 406 within the openings 202A, 202B, 202C, respectively. In some examples, the first layer 404 and the second layer 406 include a resin-coated copper (RCC).

FIG. 5 is a cross-sectional schematic view of an example third intermediate stage 500 of the assembly/manufacturing of the glass core 200 of FIG. 2A. In some examples, the third intermediate stage 500 can occur after the second intermediate stage 400. In the illustrated example of FIG. 5, the glass core 200 and the multi-layer conductive film 402 have been flipped such that the first surface 204 is above the second layer 406 (e.g., oriented as depicted in FIG. 2A, etc.). During the third intermediate stage 500, the vias 208A, 208B, 208C are deposited within the openings 202A, 202B, 202B. For example, the conductive material 210 of the vias 208A, 208B, 208C can be electroplated via electrolyte plating. In some such examples, the glass core 200 is positioned within a bath (e.g., sulfuric acid, etc.) and an electric current is transmitted through the first layer 404 by coupling the first layer 404 to two electrodes and inducing a current therebetween, which causes the exposed portions 408A, 408B, 408C of the second layer 406 to act as a cathode. In some such examples, the conductive material 210 is gradually deposited (e.g., plated, etc.) onto the exposed portions 408A, 408B, 408C, which creates the vias 208A, 208B, 208C.

In the illustrated example of FIG. 5, the vias 208A, 208B, 208C are deposited from the bottom of the glass core 200 (e.g., the second surface 206, etc.) toward the top of the glass core 200 (e.g., the first surface 204, etc.) (e.g., not from the side walls of the openings 202A, 202B, 202B, etc.). That is, the vias 208A, 208B, 208C are deposited via bottom-up plating. In some examples, because the vias 208A, 208B, 208C are plated from the second surface 206 and the not side walls of the openings 202A, 202B, 202C, at least one gap, cavity, and/or pocket (e.g., similar to the gap 218 of FIG. 2B, etc.) are formed between the vias 208A, 208B, 208C and the side walls of the openings 202A, 202B, 202C. Furthermore, the bottom-up plating of the vias 208A, 208B, 208C during the third intermediate stage 500 of FIG. 5 prevents voids associated with the premature bridging of the openings 202A, 202B, 202C from forming in the conductive material of the vias 208A, 208B, 208C. That is, the vias 208A, 208B, 208C of this example are voidless (e.g., the vias 208A, 208B, 208C are voidless interconnects, etc.). The prevention of the formation of voids associated with the bottom-up plating of the vias 208A, 208B, 208C enables the openings 202A, 202B, 202C to be deposited with high aspect ratios (e.g., aspect ratios greater than 8:1, etc.). In the illustrated example of FIG. 5, the electroplating of the vias 208A, 208B, 208C creates an example first overhang 502A, 502B, 502C on the first surface 204 of the glass core 200. As used herein, the overhangs 502A, 502B, 502C are also referred to as “overburdens.”

FIG. 6 is a cross-sectional schematic view of an example fourth intermediate stage 600 of the assembly/manufacturing of the glass core 200 of FIG. 2A. In some examples, the fourth intermediate stage 600 can occur after the third intermediate stage 500. During the fourth intermediate stage 600, the first surface 204 of the glass core 200 is planarized, which removes the overhangs 502A, 502B, 502C of FIG. 5 from the first surface 204. For example, the first surface 204 can be planarized via chemical-mechanical polishing. In other examples, the first surface 204 can be planarized in another suitable process (e.g., laser planarization, etc.).

FIG. 7 is a cross-sectional schematic view of an example fifth intermediate stage 700 of the assembly/manufacturing of the glass core 200 of FIG. 2A. In some examples, the fifth intermediate stage 700 can occur after the fourth intermediate stage 600. During the fifth intermediate stage 700, an example protective film 702 is deposited on the first surface 204. For example, the protective film 702 can be deposited via a thin film deposition (TFD) process. In other examples, the protective film 702 can be deposited via a different method (e.g., lamination, a vapor deposition process, etc.). In some examples, the protective film 702 is an ultraviolet (UV) polymer release film (e.g., the adhesion of the protective film 702 to the first surface 204 can be released via the application of UV light, etc.). In other examples, the protective film 702 is a heat release film and/or another type of protective film.

FIG. 8 is a cross-sectional schematic view of an example sixth intermediate stage 800 of the assembly/manufacturing of the glass core 200 of FIG. 2A. In some examples, the sixth intermediate stage 800 can occur after the fifth intermediate stage 700. During the sixth intermediate stage 800, the glass core 200 is rotated 180 degrees (e.g., flipped, etc.) and the multi-layer conductive film 402 is removed from the glass core 200. For example, some or all of the multi-layer conductive film 402 can be removed via etching (e.g., dry etching, wet etching, etc.). Additionally or alternatively, some or all of the multi-layer conductive film 402 can be removed via planarization of the second surface 206 (e.g., chemical-mechanical planarization, etc.). In some examples, the protective film 702 protects the glass of the glass core 200 and the conductive material 210 of the vias 208A, 208B, 208C near the first surface 204 from the etching process associated with the intermediate stage 800.

FIG. 9 is a cross-sectional schematic view of an example seventh intermediate stage 900 of the assembly/manufacturing of the glass core 200 of FIG. 2A. In some examples, the seventh intermediate stage 900 can occur after the sixth intermediate stage 800. During the seventh intermediate stage 900, the protective film 702 of FIG. 7 is removed and the glass core 200 is rotated 180 degrees (e.g., flipped, oriented to have the orientation of FIG. 2A, etc.). In some examples, the protective film 702 is removed via the application of UV light. In other examples, the protective film 702 can be removed via another process (e.g., the application of heat, the application of a different wavelength of light, etc.).

FIGS. 10-15 illustrate different intermediate stages in an example second fabrication process to manufacture an example glass core 1002 with example vias 1402 (e.g., conductive interconnects, etc.) implemented in accordance with teachings of this disclosure. The glass core 1002 and vias 1402 are similar to the glass core 200 of FIG. 2A and the vias 208A, 208B, 208C of FIG. 2A, respectively, except as noted otherwise. It should be appreciated that some or all of the intermediate stages of FIGS. 10-15 can be performed in addition to and/or substituted for corresponding intermediate stages of the first fabrication process associated with FIGS. 3-9 to manufacture the glass core 200 of FIGS. 2A and 2B. Similarly, it should be appreciated that some or all of the intermediate stages of FIGS. 3-9 can be performed in addition to and/or substituted for corresponding intermediate stages of the second fabrication process associated with FIGS. 10-15 to manufacture the glass core 1002. Example operations to manufacture the glass core 200 of FIGS. 2A and 2B via some or all of the intermediate stages of FIGS. 3-9 and/or the glass core 1002 the intermediate stages of FIGS. 10-15 are described below in conjunction with FIG. 16.

FIG. 10 is a cross-sectional schematic view of an example first intermediate stage 1000 of the assembly/manufacturing of a glass core subassembly associated with the glass core 1002. During the first intermediate stage 1000, the glass core 1002 is provided. In the illustrated example of FIG. 10, the glass core 1002 includes example openings 1004, which extend between an example first surface 1006 of the glass core 1002 and an example second surface 1008 of the glass core 1002. The surfaces 1006, 1008 are similar to the surfaces 204, 206 of FIG. 2A, respectively, except as noted otherwise. The openings 1004 are similar to the openings 202A, 202B, 202C of FIG. 2A, except as noted otherwise. For example, the openings 1004 can be formed via a LIDE process similar to the process described in conjunction with the first intermediate stage 300 of FIG. 3. In other examples, the openings 1004 can be created via one or more different operation(s), such as drilling.

In the illustrated example of FIG. 10, the openings 1004 are straight-walled, which is facilitated by the bottom-up plating of vias associated with the intermediate stage of FIG. 14. That is, the openings 1004 have a substantially constant width along the length of the glass core 1002. In other examples, the openings 1004 can have another suitable shape (e.g., a tapered shape, an hourglass shape, etc.).

FIG. 11 is a cross-sectional schematic view of an example second intermediate stage 1100 of the assembly/manufacturing of the glass core 1002 of FIG. 15. In some examples, the second intermediate stage 1100 can occur after the first intermediate stage 1000 of FIG. 10. During the second intermediate stage 1100, an example adhesion promoter 1104 has been deposited on an example interior walls 1102 of the openings 1004. For example, the adhesion promoter 1104 can be deposited on the interior walls 1102 via atomic layer deposition (ALD) and/or chemical vapor deposition. In some examples, the adhesion promoter is imidazole. In other examples, a different adhesion promoter can be deposited on the interior walls 1102. In some examples, the adhesion promoter 1104 has a thickness of less than 10 nanometers. In some examples, the deposition of the adhesion promoter 1104 can be omitted. The adhesion promoter 1104 is not depicted in the FIGS. 12-15 for the interest of visual clarity.

FIG. 12 is a cross-sectional schematic view of an example third intermediate stage 1200 of the assembly/manufacturing of the glass core 1002 of FIG. 15. In some examples, the third intermediate stage 1200 can occur after the second intermediate stage 1100. During the third intermediate stage 1200, an example multi-layer conductive film 1202 has been coupled to the second surface 1008 of the glass core 1002. In the illustrated example of FIG. 12, the multi-layer conductive film 1202 includes an example first layer 1204, an example second layer 1206, and an example third layer 1208. In some examples, the multi-layer conductive film 1202 can be coupled to the second surface 1008 of the glass core 1002 via a foil deposition technique. In other examples, the multi-layer conductive film 1202 can be coupled to the second surface 1008 via a different process (e.g., mechanical deposition, etc.). As used herein, the multi-layer conductive film 1202 is also referred to as a multi-layer conductive laminate. In the illustrated example of FIG. 12, the first layer 1204 is between the second layer 1206 and the third layer 1208. In the illustrated example of FIG. 12, the second layer 1206 is adjacent to and abutting the second surface 1008 (e.g., the second layer 1206 is adhered to the second surface 1008, etc.). In the illustrated example of FIG. 12, the third surface 1208 is distal to the second surface 1008.

The first layer 1204 of the multi-layer conductive film 1202 is an electrode film layer. The first layer 1204 is similar to the first layer 404 of FIG. 4, except as noted otherwise. For example, the first layer 1204 can be implemented by a metal film and/or RCC. In other examples, the first layer 1204 can be implemented by any other suitable conductive material. In the illustrated example of FIG. 12, the first layer 1204 includes an example first tab 1210A and an example second tab 1210B, which extend planarly from the second layer 1206 and the third layer 1208. The tabs 1210A, 1210B facilitate the coupling of the first layer 1204 to an electricity source. The second layer 1206 of the multi-layer conductive film 1202 is an electrically conductive adhesive film. The second layer 1206 is a doped conductive adhesive and is similar to the second layer 406 of FIG. 4, except as noted otherwise. For example, the second layer 1206 can be implemented by a copper particle-doped resin. In other examples, the second layer 1206 can be implemented by any other suitable conductive adhesive. In some examples, the second layer 1206 can include an activator for electroless copper plating, such as a palladium activator. In other examples, if the electroless copper plating is not to occur, the second layer 1206 does not include an activator. The third layer 1208 of the multi-layer conductive film 1202 is a non-conductive backing layer. In some examples, the third layer 1208 can be implemented by a polymer film (e.g., a plastic film, etc.). The third layer 1208 prevents the electroplating of the second layer 1206 opposite the glass core 1002. In other examples, the third layer 1208 is absent. In the illustrated example of FIG. 12, the deposition of the multi-layer conductive film 1202 on the glass core 200 creates example exposed portions 1212 on the second layer 1206 within the openings 1004.

FIG. 13 is a cross-sectional schematic view of an example fourth intermediate stage 1300 of the assembly/manufacturing of the glass core 1002 of FIG. 15. In some examples, the fourth intermediate stage 1300 can occur after the third intermediate stage 1200. During the fourth intermediate stage 1300, example preliminary seed layers 1302 have been deposited on the exposed portions 1212 of the second layer 1206 of the multi-layer conductive film 1202. In some examples, the glass core 1002 can be deposited with a bath including a dissolved metal ion (e.g., a copper ion, etc.). In some such examples, the activator (e.g., a palladium activator, etc.) in the second layer 1206 causes thin layers of the copper ion to be deposited on the exposed portions 1212 as the preliminary seed layers 1302 via electroless plating. In other examples, the preliminary seed layers 1302 can be deposited via another suitable process (e.g., lithography, atomic layer deposition (ALD), chemical vapor deposition (CVD), etc.). In some examples, the intermediate stage 1300 of FIG. 13 is omitted and the preliminary seed layers 1302 are absent. In such examples, vias can be electroplated directly on the exposed portions 1212 (e.g., via an intermediate stage similar to the third intermediate stage 500 of FIG. 5, etc.). In the illustrated example of FIG. 13, an example first electrode 1304A and an example second electrode 1304B are coupled to the tabs 1210A, 1210B, respectively. In some such examples, the electrodes 1304A, 1304B can induce a current through the first layer 1204 and the second layer 1206 during the intermediate stage of FIG. 14.

FIG. 14 is a cross-sectional schematic view of an example fifth intermediate stage 1400 of the assembly/manufacturing of the glass core 1002 of FIG. 15. In some examples, the fifth intermediate stage 1400 can occur after the fourth intermediate stage 1300. During the fifth intermediate stage 1400, example vias 1402 have been deposited within the openings 1004. For example, the vias 1402 can be electroplated onto the exposed portions 1212 of the second layer 1206 via electrolyte plating. In some examples, the glass core 200 is positioned within a bath (e.g., sulfuric acid, etc.) and an electric current is induced through the first layer 1204 via the electrodes 1304A, 1304B. The induced current causes the preliminary seed layers 1302 and/or the exposed portions 1212 of the second layer 1206 to act as a cathode. In some such examples, the conductive material of the vias 1402 is gradually deposited (e.g., plated, etc.) onto the preliminary seed layer 1302 of FIG. 13. In the illustrated example of FIG. 14, the vias 1402 are deposited from the bottom of the glass core 1002 (e.g., the second surface 1008, etc.) toward the top of the glass core 1002 (e.g., the first surface 1006, etc.) (e.g., not from the side walls of the openings 1004, etc.). That is, the vias 1402 are deposited via bottom-up plating. In some examples, because the vias 1402 are plated from the second surface 1008 and not the side walls of the openings 1004, at least one gap, cavity, and/or pocket (e.g., a gap similar to the gap 218 of FIG. 2B, etc.) are formed between the vias 1402 and the side walls (e.g., the interior walls 1102, etc.) of the openings 1004 of the glass core 1002.

The bottom-up plating of the vias 1402 reduces (e.g., prevents, etc.) the formation of voids within the conductive material of the vias. That is, the vias 1402 of this example are voidless (e.g., the vias 1402 are voidless interconnects, etc.). In some examples, the bottom-up plating of the vias 1402 facilitates the straight wall shape of the openings 1004 and the vias 1402 (e.g., the vias 1402 have a cylindrical shape, the vias 1402 have an approximately constant cross-sectional area along the length of the glass core 1002, etc.). In some examples, the bottom-up plating of the vias 1402 enables the openings 1004 and the vias 1402 to have aspect ratios that are greater than or equal to 8:1. In the illustrated example of FIG. 14, the electroplating of the vias 1402 creates example overhangs 1404 on the first surface 1006 of the glass core 1002.

FIG. 15 is a cross-sectional schematic view of an example sixth intermediate stage 1500 of the assembly/manufacturing of the glass core 1002 of FIG. 15. In some examples, the sixth intermediate stage 1500 can occur after the fifth intermediate stage 1400. During the sixth intermediate stage 1500, the multilayer conductive film 1202 has been removed from the second surface 1008. In the illustrated example of FIG. 15, the first surface 1006 and the second surface 1008 have been planarized, which removes the overhangs 1404 of FIG. 14 from the first surface 1006. For example, the first surface 1006 and/or the second surface 1008 can be planarized via chemical-mechanical polishing. In other examples, the first surface 1006 and/or the second surface 1008 can be planarized in another suitable process.

FIG. 16 is a flowchart representative of example operations 1600 that may be performed to fabricate any one of the example glass core 200 of FIGS. 2A and 2B via the intermediate stages 300, 400, 500, 600, 700, 800, 900 of FIGS. 3-9 and/or the glass core 1002 via the intermediate stages 1000, 1100, 1200, 1300, 1400, 1500 of FIGS. 10-15. In some examples, some or all of the operations 1600 described with reference to FIG. 16 are performed automatically by equipment that is programmed to perform the operations 1600.

Although the example operations 1600 is described with reference to the flowchart illustrated in FIG. 16, many other operations may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method of FIG. 16 begins at block 1602, at which a glass core is prepared. For example, the glass core 200 of FIG. 2A and/or the glass core 1002 of FIG. 10 can be prepared. In some examples, the glass core 200 and/or the glass core 1002 can be prepared by casting a glass mixture in a planar shape. In other examples, the glass core 200 and/or the glass core 1002 can be prepared in any other suitable manner. In some examples, the glass core 200 and/or the glass core 1002 can be positioned in a fabrication environment. At block 1604, openings are created in the glass core 200 and/or the glass core 1002. For example, the openings 202A, 202B, 202C can be formed in the glass core 200, and/or the openings 1004 can be formed in the glass core 1002 via a LIDE process. In other examples, the openings 202A, 202B, 202C, and/or the openings 1004 can be formed via a different process (e.g., mechanical drilling, laser drilling, etc.). The point of fabrication after completion of block 1604 corresponds to the structure of the first intermediate stage 300 of FIG. 3 and/or the structure of the first intermediate stage 1000 of FIG. 10.

At block 1606, it is determined if an adhesion promoter is to be deposited in the openings created during the execution of block 1604. In some examples, the determination of whether an adhesion promoter is to be deposited is based on the geometry of the openings, the thickness of the glass cores, and/or another characteristic of the openings and/or core. If the glass core 1002 of FIG. 10 is to be manufactured via the operations 1600, an adhesion promoter is to be deposited. If an adhesion promoter is to be deposited, the operations 1600 advance to block 1608. If an adhesion promoter is not to be deposited, the operations 1600 advance to block 1610. At block 1608, the adhesion promoter 1104 is deposited on the side wall 1102. For example, the adhesion promoter 1104 can be deposited as a thin layer on the side walls 1102. In some examples, the adhesion promoter 1104 is imidazole. In other examples, the adhesion promoter 1104 can be implemented by another suitable substance. The point of fabrication after completion of block 1604 corresponds to the structure of the second intermediate stage 1100 of FIG. 11.

At block 1610, a multilayer conductive film is coupled to the glass core. For example, the multi-layer conductive film 402 of FIG. 4 can be coupled to the glass core 200 and/or the multi-layer conductive film 1202 of FIG. 12 can be coupled to the glass core 1002 of FIG. 10. In some examples, the multi-layer conductive films 402, 1202 can be coupled to the second surfaces 206, 1008 of the glass cores 200, 1002, respectively, via a thin film deposition (TFD) technique. In other examples, the multi-layer conductive films 402, 1202 can be deposited via a different technique. The point of fabrication after completion of block 1610 corresponds to the structure of the second intermediate stage 400 of FIG. 4 and/or the structure of the third intermediate stage 1200 of FIG. 12.

At block 1612, it is determined if preliminary seed layers are to be deposited. In some examples, the determination of whether preliminary seed layers are to be deposited is based on the conductivity and/or the suitability for electroplating of the adhesive layer of the multilayer conductive film (e.g., the second layer 406 of the multi-layer conductive film 402 of FIG. 4, the second layer 1206 of the multi-layer conductive film 1202 of FIG. 12, etc.). If the glass core 1002 of FIG. 10 is to be manufactured via the operations 1600, preliminary seed layers are to be deposited. If preliminary seed layers are not to be deposited, the operations 1600 advance to block 1614. If preliminary seed layer is not to be deposited, the operations 1600 advance to block 1616. At block 1614, the preliminary seed layers 1302 are deposited on the exposed portions 1212 of the second layer 1206. For example, the preliminary seed layers 1302 can be deposited via electroless plating. In other examples, the preliminary seed layers 1302 can be deposited via another technique (e.g., lithography, a vapor deposition technique, etc.).

At block 1616, the multilayer conductive film is coupled to an electrode. For example, the first layer 404 of the multi-layer conductive film 402 and/or the first layer 1204 of the multi-layer conductive film 1202 can be coupled to an electricity source to induce a current therethrough. In some examples, the tabs 1210A, 1210B of the multi-layer conductive film 1202 can be coupled to the electrodes 1304A, 1304B. The point of fabrication after completion of block 1616 corresponds to the structure immediately prior to the third intermediate stage 500 of FIG. 5 and/or the structure of the fourth intermediate stage 1300 of FIG. 13.

At block 1618, vias are electroplated into the openings of the glass core. For example, the vias 208A, 208B, 208C of FIG. 2A and/or the vias 1402 of FIG. 14 can be formed via electroplating. In some examples, the vias 208A, 208B, 208C of FIG. 2A and/or the vias 1402 of FIG. 14 can be electroplated on the exposed portions of the multi-layer conductive films 402, 1202 and/or the preliminary seed layer 1302 deposited during the execution of block 1614. In some examples, the bottom-up plating of the vias 208A, 208B, 208C of FIG. 2A and/or the vias 1402 of FIG. 14 prevents the formation of voids therein and creates at least gap, pocket, and/or cavity between the vias 208A, 208B, 208C of FIG. 2A and/or the vias 1402 of FIG. 14 and the interior walls of glass cores 200, 1002, respectively. The point of fabrication after completion of block 1618 corresponds to the structure of the third intermediate stage 500 of FIG. 5 and/or the structure of the fifth intermediate stage 1400 of FIG. 14.

At block 1620, a first surface of the glass core is planarized. For example, the first surface 204 of the glass core 200 and/or the first surface 1006 of the glass core 1002 can be planarized via chemical mechanical polishing. In other examples, the first surface 204 of the glass core 200 and/or the first surface 1006 of the glass core 1002 can be planarized in another suitable manner. The point of fabrication after completion of block 1618 corresponds to the structure of the fourth intermediate stage 600 of FIG. 5. At block 1622, a protective film is coupled to the first surface of the glass core. For example, the protective film 702 can be coupled to the first surface 204 of the glass core 200 via a thin film deposition technique. In other examples, the protective film 702 can be deposited via a different deposition technique. In some examples, the execution of block 1622 can be omitted. The point of fabrication after completion of block 1622 corresponds to the structure of the fifth intermediate stage 700 of FIG. 7.

At block 1624, the multilayer conductive film is removed from the glass core. For example, the multi-layer conductive film 402 of FIG. 4 and/or the multi-layer conductive film 1202 of FIG. 12 can be removed mechanically. In other examples, the multi-layer conductive film 402 of FIG. 4 and/or the multi-layer conductive film 1202 of FIG. 12 can be removed via planarization and/or etching (e.g., drying etching, wet etching, etc.). The point of fabrication after completion of block 1624 corresponds to the structure of the fifth intermediate stage 700 of FIG. 7. At block 1626, the second surface of the glass core is planarized. For example, the second surface 206 of the glass core 200 and/or the second surface 1008 of the glass core 1002 can be planarized via chemical mechanical polishing. In other examples, the second surface 206 of the glass core 200 and/or the second surface 1008 of the glass core 1002 can be planarized in another suitable manner. The operations 1600 end.

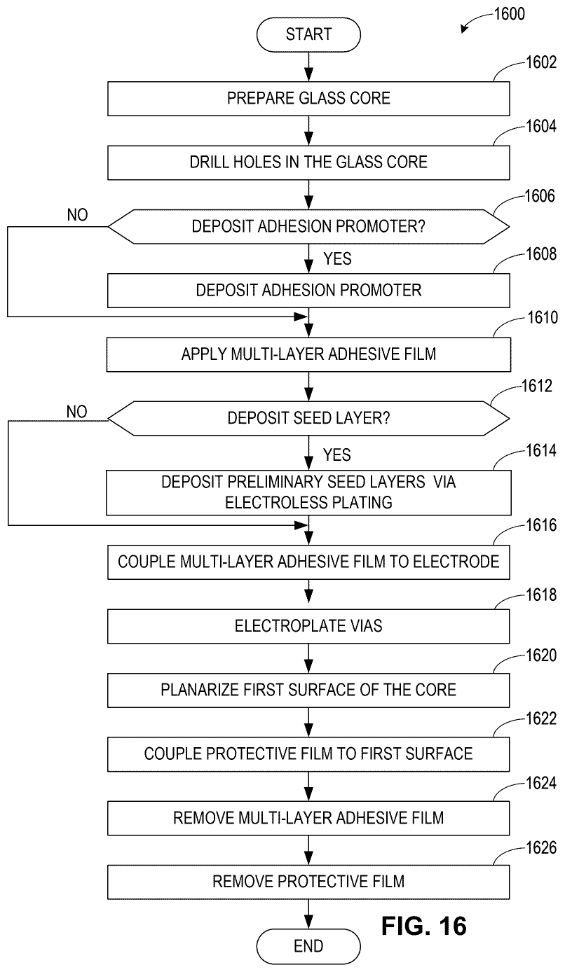

The example IC package 100 of FIG. 1 including the glass core 200 of FIG. 2 and/or the glass core 1002 of FIG. 10 may be included in any suitable electronic component. FIGS. 17-20 illustrate various examples of apparatus that may include or be included in the IC package 100 disclosed herein.

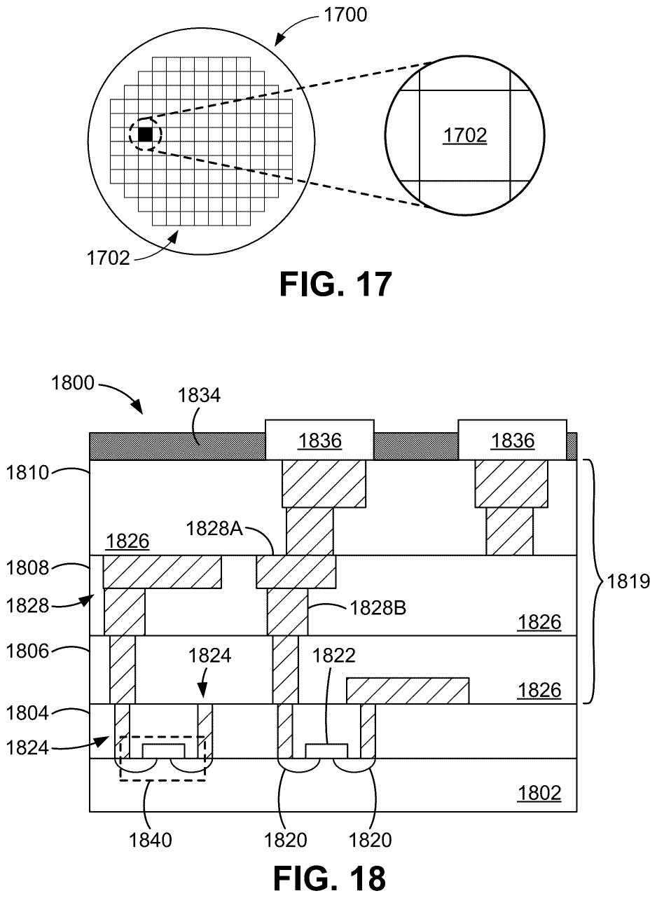

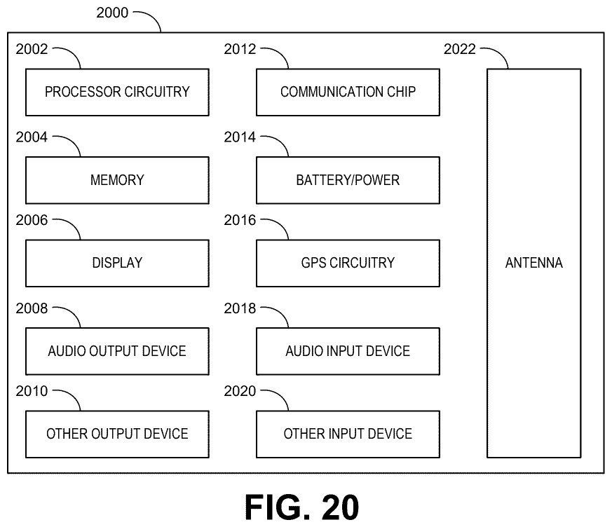

FIG. 17 is a top view of a wafer 1700 and dies 1702 that may be included in the IC package 100 of FIG. 1 (e.g., as any suitable ones of the dies 108, 110). The wafer 1700 includes semiconductor material and one or more dies 1702 having circuitry. Each of the dies 1702 may be a repeating unit of a semiconductor product. After the fabrication of the semiconductor product is complete, the wafer 1700 may undergo a singulation process in which the dies 1702 are separated from one another to provide discrete “chips.” The die 1702 includes one or more transistors (e.g., some of the transistors 1840 of FIG. 18, discussed below), supporting circuitry to route electrical signals to the transistors, passive components (e.g., traces, resistors, capacitors, inductors, and/or other circuitry), and/or any other components. In some examples, the die 1702 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die (e.g., the die 1702, etc.). For example, a memory array of multiple memory circuits may be formed on a same die (e.g., die 1702 as programmable circuitry (e.g., the processor circuitry 2002 of FIG. 20) and/or other logic circuitry. Such memory may store information for use by the programmable circuitry. The example IC package 100 disclosed herein may be manufactured using a die-to-wafer assembly technique in which some dies are attached to a wafer 1700 that includes others of the dies, and the wafer 1700 is subsequently singulated.

FIG. 18 is a cross-sectional side view of an IC device 1800 that may be included in the example IC package 100 (e.g., in any one of the dies 108, 110). One or more of the IC devices 1800 may be included in one or more dies 1702 (FIG. 17). The IC device 1800 may be formed on a die substrate 1802 (e.g., the wafer 1700 of FIG. 17) and may be included in a die (e.g., the die 1702 of FIG. 17). The die substrate 1802 may be a semiconductor substrate including semiconductor materials including, for example, n-type or p-type materials systems (or a combination of both). The die substrate 1802 may include, for example, a crystalline substrate formed using a bulk silicon or a silicon-on-insulator (SOI) substructure. In some examples, the die substrate 1802 may be formed using alternative materials, which may or may not be combined with silicon, which include but are not limited to germanium, indium antimonide, lead telluride, indium arsenide, indium phosphide, gallium arsenide, or gallium antimonide. Further materials classified as group II-VI, III-V, or IV may also be used to form the die substrate 1802. Although a few examples of materials from which the die substrate 1802 may be formed are described here, any material that may serve as a foundation for an IC device 1800 may be used. The die substrate 1802 may be part of a singulated die (e.g., the dies 1702 of FIG. 17) or a wafer (e.g., the wafer 1700 of FIG. 17).

The IC device 1800 may include one or more device layers 1804 disposed on and/or above the die substrate 1802. The device layer 1804 may include features of one or more transistors 1840 (e.g., metal oxide semiconductor field-effect transistors (MOSFETs)) formed on the die substrate 1802. The device layer 1804 may include, for example, one or more source and/or drain (S/D) regions 1820, a gate 1822 to control current flow between the S/D regions 1820, and one or more S/D contacts 1824 to route electrical signals to/from the S/D regions 1820. The transistors 1840 may include additional features not depicted for the sake of clarity, such as device isolation regions, gate contacts, and the like. The transistors 1840 are not limited to the type and configuration depicted in FIG. 18 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1840 may include a gate 1822 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1840 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1840 along the source-channel-drain direction, the gate electrode may include a U-shaped structure that includes a bottom portion substantially parallel to the surface of the die substrate 1802 and two sidewall portions that are substantially perpendicular to the top surface of the die substrate 1802. In other examples, at least one of the metal layers that form the gate electrode may be a planar layer that is substantially parallel to the top surface of the die substrate 1802 and does not include sidewall portions substantially perpendicular to the top surface of the die substrate 1802. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1820 may be formed within the die substrate 1802 adjacent to the gate 1822 of corresponding transistor(s) 1840. The S/D regions 1820 may be formed using an implantation/diffusion process or an etching/deposition process, for example. In the former process, dopants such as boron, aluminum, antimony, phosphorous, or arsenic may be ion-implanted into the die substrate 1802 to form the S/D regions 1820. An annealing process that activates the dopants and causes them to diffuse farther into the die substrate 1802 may follow the ion-implantation process. In the latter process, the die substrate 1802 may first be etched to form recesses at the locations of the S/D regions 1820. An epitaxial deposition process may then be carried out to fill the recesses with material that is used to fabricate the S/D regions 1820. In some implementations, the S/D regions 1820 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1820 may be formed using one or more alternate semiconductor materials such as germanium or a group III-V material or alloy. In further examples, one or more layers of metal and/or metal alloys may be used to form the S/D regions 1820.

Electrical signals, such as power and/or input/output (I/O) signals, may be routed to and/or from the devices (e.g., transistors 1840) of the device layer 1804 through one or more interconnect layers disposed on the device layer 1804 (illustrated in FIG. 18 as interconnect layers 1806-1810). For example, electrically conductive features of the device layer 1804 (e.g., the gate 1822 and the S/D contacts 1824) may be electrically coupled with the interconnect structures 1828 of the interconnect layers 1806-1810. The one or more interconnect layers 1806-1810 may form a metallization stack (also referred to as an “ILD stack”) 1819 of the IC device 1800.

The interconnect structures 1828 may be arranged within the interconnect layers 1806-1810 to route electrical signals according to a wide variety of designs (in particular, the arrangement is not limited to the particular configuration of interconnect structures 1828 depicted in FIG. 18). Although a particular number of interconnect layers 1806-1810 is depicted in FIG. 18, examples of the present disclosure include IC devices having more or fewer interconnect layers than depicted.

In some examples, the interconnect structures 1828 may include lines 1828A and/or vias 1828B filled with an electrically conductive material such as a metal. The lines 1828A may be arranged to route electrical signals in a direction of a plane that is substantially parallel with a surface of the die substrate 1802 upon which the device layer 1804 is formed. For example, the lines 1828A may route electrical signals in a direction in and/or out of the page from the perspective of FIG. 18. The vias 1828B may be arranged to route electrical signals in a direction of a plane that is substantially perpendicular to the surface of the die substrate 1802 upon which the device layer 1804 is formed. In some examples, the vias 1828B may electrically couple lines 1828A of different interconnect layers 1806-1810 together.

The interconnect layers 1806-1810 may include a dielectric material 1826 disposed between the interconnect structures 1828, as shown in FIG. 18. In some examples, the dielectric material 1826 disposed between the interconnect structures 1828 in different ones of the interconnect layers 1806-1810 may have different compositions; in other examples, the composition of the dielectric material 1826 between different interconnect layers 1806-1810 may be the same.

A first interconnect layer 1806 (referred to as Metal 1 or “M1”) may be formed directly on the device layer 1804. In some examples, the first interconnect layer 1806 may include lines 1828A and/or vias 1828B, as shown. The lines 1828A of the first interconnect layer 1806 may be coupled with contacts (e.g., the S/D contacts 1824) of the device layer 1804.

A second interconnect layer 1808 (referred to as Metal 2 or “M2”) may be formed directly on the first interconnect layer 1806. In some examples, the second interconnect layer 1808 may include vias 1828B to couple the lines 1828A of the second interconnect layer 1808 with the lines 1828A of the first interconnect layer 1806. Although the lines 1828A and the vias 1828B are structurally delineated with a line within each interconnect layer (e.g., within the second interconnect layer 1808) for the sake of clarity, the lines 1828A and the vias 1828B may be structurally and/or materially contiguous (e.g., simultaneously filled during a dual-damascene process) in some examples.

A third interconnect layer 1810 (referred to as Metal 3 or “M3”) (and additional interconnect layers, as desired) may be formed in succession on the second interconnect layer 1808 according to similar techniques and/or configurations described in connection with the second interconnect layer 1808 or the first interconnect layer 1806. In some examples, the interconnect layers that are “higher up” in the metallization stack 1819 in the IC device 1800 (i.e., further away from the device layer 1804) may be thicker.

The IC device 1800 may include a solder resist material 1834 (e.g., polyimide or similar material) and one or more conductive contacts 1836 formed on the interconnect layers 1806-1810. In FIG. 18, the conductive contacts 1836 are illustrated as taking the form of bond pads. The conductive contacts 1836 may be electrically coupled with the interconnect structures 1828 and configured to route the electrical signals of the transistor(s) 1840 to other external devices. For example, solder bonds may be formed on the one or more conductive contacts 1836 to mechanically and/or electrically couple a chip including the IC device 1800 with another component (e.g., a circuit board). The IC device 1800 may include additional or alternate structures to route the electrical signals from the interconnect layers 1806-1810; for example, the conductive contacts 1836 may include other analogous features (e.g., posts) that route the electrical signals to external components.

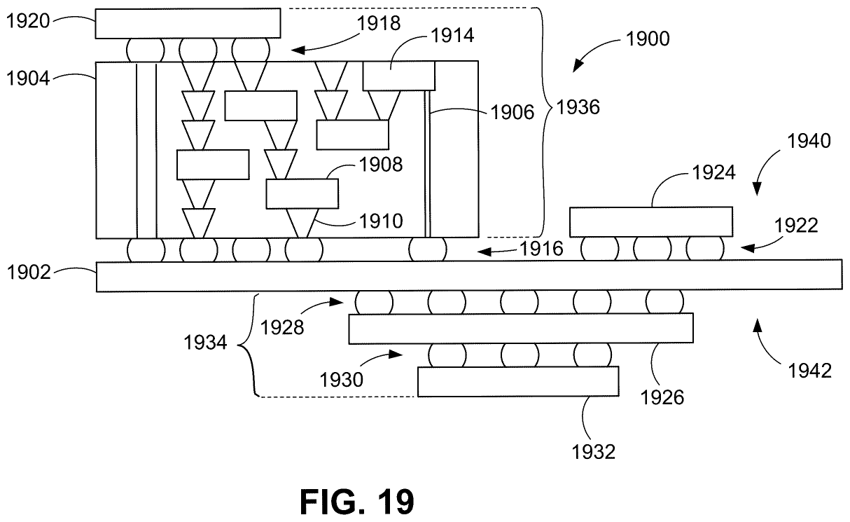

FIG. 19 is a cross-sectional side view of an IC device assembly 1900 that may include the IC package 100 disclosed herein. In some examples, the IC device assembly corresponds to the IC package 100. The IC device assembly 1900 includes a number of components disposed on a circuit board 1902 (which may be, for example, a motherboard). The IC device assembly 1900 includes components disposed on a first face 1940 of the circuit board 1902 and an opposing second face 1942 of the circuit board 1902; generally, components may be disposed on one or both faces 1940 and 1942. Any of the IC packages discussed below with reference to the IC device assembly 1900 may take the form of the example IC package 100 of FIG. 1.

In some examples, the circuit board 1902 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1902. In other examples, the circuit board 1902 may be a non-PCB substrate.

The IC device assembly 1900 illustrated in FIG. 19 includes a package-on-interposer structure 1936 coupled to the first face 1940 of the circuit board 1902 by coupling components 1916. The coupling components 1916 may electrically and mechanically couple the package-on-interposer structure 1936 to the circuit board 1902, and may include solder balls (as shown in FIG. 19), male and female portions of a socket, an adhesive, an underfill material, and/or any other suitable electrical and/or mechanical coupling structure.

The package-on-interposer structure 1936 may include an IC package 1920 coupled to an interposer 1904 by coupling components 1918. The coupling components 1918 may take any suitable form for the application, such as the forms discussed above with reference to the coupling components 1916. Although a single IC package 1920 is shown in FIG. 19, multiple IC packages may be coupled to the interposer 1904; indeed, additional interposers may be coupled to the interposer 1904. The interposer 1904 may provide an intervening substrate used to bridge the circuit board 1902 and the IC package 1920. The IC package 1920 may be or include, for example, a die (the die 1702 of FIG. 17), an IC device (e.g., the IC device 1800 of FIG. 18), or any other suitable component. Generally, the interposer 1904 may spread a connection to a wider pitch or reroute a connection to a different connection. For example, the interposer 1904 may couple the IC package 1920 (e.g., a die) to a set of BGA conductive contacts of the coupling components 1916 for coupling to the circuit board 1902. In the example illustrated in FIG. 19, the IC package 1920 and the circuit board 1902 are attached to opposing sides of the interposer 1904; in other examples, the IC package 1920 and the circuit board 1902 may be attached to a same side of the interposer 1904. In some examples, three or more components may be interconnected by way of the interposer 1904.

In some examples, the interposer 1904 may be formed as a PCB, including multiple metal layers separated from one another by layers of dielectric material and interconnected by electrically conductive vias. In some examples, the interposer 1904 may be formed of an epoxy resin, a fiberglass-reinforced epoxy resin, an epoxy resin with inorganic fillers, a ceramic material, or a polymer material such as polyimide. In some examples, the interposer 1904 may be formed of alternate rigid or flexible materials that may include the same materials described above for use in a semiconductor substrate, such as silicon, germanium, and other group III-V and group IV materials. The interposer 1904 may include metal interconnects 1908 and vias 1910, including but not limited to through-silicon vias (TSVs) 1906. The interposer 1904 may further include embedded devices 1914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1904. The package-on-interposer structure 1936 may take the form of any of the package-on-interposer structures known in the art.

The IC device assembly 1900 may include an IC package 1924 coupled to the first face 1940 of the circuit board 1902 by coupling components 1922. The coupling components 1922 may take the form of any of the examples discussed above with reference to the coupling components 1916, and the IC package 1924 may take the form of any of the examples discussed above with reference to the IC package 1920.

The IC device assembly 1900 illustrated in FIG. 19 includes a package-on-package structure 1934 coupled to the second face 1942 of the circuit board 1902 by coupling components 1928. The package-on-package structure 1934 may include a first IC package 1926 and a second IC package 1932 coupled together by coupling components 1930 such that the first IC package 1926 is disposed between the circuit board 1902 and the second IC package 1932. The coupling components 1928, 1930 may take the form of any of the examples of the coupling components 1916 discussed above, and the IC packages 1926, 1932 may take the form of any of the examples of the IC package 1920 discussed above. The package-on-package structure 1934 may be configured in accordance with any of the package-on-package structures known in the art.

FIG. 20 is a block diagram of an example electrical device 2000 that may include one or more of the example IC package 100. For example, any suitable ones of the components of the electrical device 2000 may include one or more of the device assemblies 1900, IC devices 1800, or dies 1702 disclosed herein, and may be arranged in the example IC package 100. A number of components are illustrated in FIG. 20 as included in the electrical device 2000, but any one or more of these components may be omitted or duplicated, as suitable for the application. In some examples, some or all of the components included in the electrical device 2000 may be attached to one or more motherboards. In some examples, some or all of these components are fabricated onto a single system-on-a-chip (SoC) die.

Additionally, in various examples, the electrical device 2000 may not include one or more of the components illustrated in FIG. 20, but the electrical device 2000 may include interface circuitry for coupling to the one or more components. For example, the electrical device 2000 may not include a display 2006, but may include display interface circuitry (e.g., a connector and driver circuitry) to which a display 2006 may be coupled. In another set of examples, the electrical device 2000 may not include an audio input device 2018 (e.g., microphone) or an audio output device 2008 (e.g., a speaker, a headset, earbuds, etc.), but may include audio input or output device interface circuitry (e.g., connectors and supporting circuitry) to which an audio input device 2018 or audio output device 2008 may be coupled.

The electrical device 2000 may include programmable circuitry 2002 (e.g., one or more processing devices). The programmable circuitry 2002 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 2000 may include a memory 2004, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 2004 may include memory that shares a die with the programmable circuitry 2002. This memory may be used as cache memory and may include embedded dynamic random access memory (eDRAM) or spin transfer torque magnetic random access memory (STT-MRAM).

In some examples, the electrical device 2000 may include a communication chip 2012 (e.g., one or more communication chips). For example, the communication chip 2012 may be configured for managing wireless communications for the transfer of data to and from the electrical device 2000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 2012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2012 may operate in accordance with other wireless protocols in other examples. The electrical device 2000 may include an antenna 2022 to facilitate wireless communications and/or to receive other wireless communications (such as AM or FM radio transmissions).

In some examples, the communication chip 2012 may manage wired communications, such as electrical, optical, or any other suitable communication protocols (e.g., the Ethernet). As noted above, the communication chip 2012 may include multiple communication chips. For instance, a first communication chip 2012 may be dedicated to shorter-range wireless communications such as Wi-Fi or Bluetooth, and a second communication chip 2012 may be dedicated to longer-range wireless communications such as global positioning system (GPS), EDGE, GPRS, CDMA, WiMAX, LTE, EV-DO, or others. In some examples, a first communication chip 2012 may be dedicated to wireless communications, and a second communication chip 2012 may be dedicated to wired communications.

The electrical device 2000 may include battery/power circuitry 2014. The battery/power circuitry 2014 may include one or more energy storage devices (e.g., batteries or capacitors) and/or circuitry for coupling components of the electrical device 2000 to an energy source separate from the electrical device 2000 (e.g., AC line power).

The electrical device 2000 may include a display 2006 (or corresponding interface circuitry, as discussed above). The display 2006 may include any visual indicators, such as a heads-up display, a computer monitor, a projector, a touchscreen display, a liquid crystal display (LCD), a light-emitting diode display, or a flat panel display.

The electrical device 2000 may include an audio output device 2008 (or corresponding interface circuitry, as discussed above). The audio output device 2008 may include any device that generates an audible indicator, such as speakers, headsets, or earbuds.

The electrical device 2000 may include an audio input device 2018 (or corresponding interface circuitry, as discussed above). The audio input device 2018 may include any device that generates a signal representative of a sound, such as microphones, microphone arrays, or digital instruments (e.g., instruments having a musical instrument digital interface (MIDI) output).

The electrical device 2000 may include GPS circuitry 2016. The GPS circuitry 2016 may be in communication with a satellite-based system and may receive a location of the electrical device 2000, as known in the art.

The electrical device 2000 may include any other output device 2010 (or corresponding interface circuitry, as discussed above). Examples of the other output device 2010 may include an audio codec, a video codec, a printer, a wired or wireless transmitter for providing information to other devices, or an additional storage device.

The electrical device 2000 may include any other input device 2020 (or corresponding interface circuitry, as discussed above). Examples of the other input device 2020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 2000 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 2000 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientations different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that include bottom-up plating of vias in the cores of the package substrates of integrated circuit packages. Example cores disclosed herein include vias without internal voids, which enables vias with significantly higher aspect ratios than the vias of prior glass cores. Example cores disclosed herein include straight-walled (e.g., constant width, etc.) vias, which are more packaging space efficient than prior cores with hourglass-shaped vias. Examples disclosed herein do not require the deposition of a wet seed on the interior walls of the openings and agitation thereof, which is a potential source of damage in prior glass cores. Examples disclosed herein include at least one gap, pocket, and/or cavity between the vias and the interior walls of the glass core, which accommodates the thermal expansion of the via during manufacturing and operation of the glass without thermal-induced stress in the interface between the glass core and the vias.

Further examples and combinations thereof include the following:
Example 1 includes a substrate comprising a core including an opening having an internal wall, and a conductive interconnect extending through the core, the interconnect including an outer surface spaced from the internal wall by at least one gap.
Example 2 includes the substrate of any preceding example, wherein the at least one gap is less than 50 nanometers.
Example 3 includes the substrate of any preceding example, wherein the at least one gap is an air gap.
Example 4 includes the substrate of any preceding example, wherein the conductive interconnect has a cylindrical shape.
Example 5 includes the substrate of any preceding example, wherein the conductive interconnect has an aspect ratio of at least 8:1.
Example 6 includes the substrate of any preceding example, wherein the conductive interconnect is voidless.
Example 7 includes the substrate of any preceding example, wherein the core is a glass core, and the conductive interconnect is a through-glass via (TGV).
Example 8 includes a device comprising a semiconductor die, and a package substrate supporting the semiconductor die, the package substrate including a core including a side wall defining an opening, and an interconnect extending through the opening, the interconnect including an outer surface adjacent to the side wall without an intervening seed layer between the side wall and the outer surface.
Example 9 includes the device of any preceding example, wherein the side wall is spaced from the outer surface by one or more of at least one gap, at least one cavity or at least one pocket.
Example 10 includes the device of any preceding example, wherein the one or more of the at least one gap, the at least one cavity or the at least one pocket is less than 50 nanometers.
Example 11 includes the device of any preceding example, wherein the one or more of the at least one gap is an air gap.
Example 12 includes the device of any preceding example, wherein the interconnect has an approximately constant cross-sectional area along a length of the interconnect.
Example 13 includes the device of any preceding example, wherein the core is a glass core, and the interconnect is a through-glass via (TGV).
Example 14 includes the device of any preceding example, wherein the interconnect has an aspect ratio of at least 8:1.
Example 15 includes the device of any preceding example, wherein the interconnect is monolithic.
Example 16 includes an apparatus comprising a semiconductor die, a package substrate supporting the semiconductor die, the package substrate including a core including an internal wall defining an opening, and a voidless interconnect extending through the opening, the voidless interconnect having an aspect ratio of at least 8:1.
Example 17 includes the apparatus of any preceding example, wherein the core is a glass core, and the voidless interconnect is a through-glass via (TGV).
Example 18 includes the apparatus of any preceding example, wherein the voidless interconnect has an approximately constant cross-sectional area along a length of the voidless interconnect.
Example 19 includes the apparatus of any preceding example, wherein the aspect ratio is at least 20:1.
Example 20 includes the apparatus of any preceding example, wherein the voidless interconnect is spaced from the internal wall by at least one of one or more gap, one or more cavity or one or more pocket.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A substrate comprising:
a core including an opening having an internal wall; and
a conductive interconnect extending through the core, the interconnect including an outer surface spaced from the internal wall by at least one gap.

2. The substrate of claim 1, wherein the at least one gap is less than 50 nanometers.

3. The substrate of claim 1, wherein the at least one gap is an air gap.

4. The substrate of claim 1, wherein the conductive interconnect has a cylindrical shape.

5. The substrate of claim 1, wherein the conductive interconnect has an aspect ratio of at least 8:1.

6. The substrate of claim 1, wherein the conductive interconnect is voidless.

7. The substrate of claim 1, wherein the core is a glass core, and the conductive interconnect is a through-glass via (TGV).

8. A device comprising:
a semiconductor die; and
a package substrate supporting the semiconductor die, the package substrate including:
a core including a side wall defining an opening; and
an interconnect extending through the opening, the interconnect including an outer surface adjacent to the side wall without an intervening seed layer between the side wall and the outer surface.

9. The device of claim 8, wherein the side wall is spaced from the outer surface by one or more of at least one gap, at least one cavity or at least one pocket.

10. The device of claim 9, wherein the one or more of the at least one gap, the at least one cavity or the at least one pocket is less than 50 nanometers.

11. The device of claim 9, wherein the one or more of the at least one gap is an air gap.

12. The device of claim 8, wherein the interconnect has an approximately constant cross-sectional area along a length of the interconnect.

13. The device of claim 8, wherein the core is a glass core, and the interconnect is a through-glass via (TGV).

14. The device of claim 8, wherein the interconnect has an aspect ratio of at least 8:1.

15. The device of claim 8, wherein the interconnect is monolithic.

16. An apparatus comprising:
a semiconductor die;
a package substrate supporting the semiconductor die, the package substrate including:
a core including an internal wall defining an opening; and
a voidless interconnect extending through the opening, the voidless interconnect having an aspect ratio of at least 8:1.

17. The apparatus of claim 16, wherein the core is a glass core, and the voidless interconnect is a through-glass via (TGV).

18. The apparatus of claim 16, wherein the voidless interconnect has an approximately constant cross-sectional area along a length of the voidless interconnect.

19. The apparatus of claim 16, wherein the aspect ratio is at least 20:1.

20. The apparatus of claim 16, wherein the voidless interconnect is spaced from the internal wall by at least one of one or more gap, one or more cavity or one or more pocket.
